(19) United States
(12) Patent Application Publication
(10) Pub. No.: US 2014/0130855 A1
(43) Pub. Date: May 15, 2014

(54) DISPERSIVE OPTICAL SYSTEMS AND METHODS AND RELATED ELECTRICITY GENERATION SYSTEMS AND METHODS

(71) Applicant: University of Delaware, Newark, DE (US)

(72) Inventors: Tian Gu, Newark, DE (US); Michael W. Haney, Oak Hill, VA (US)

(73) Assignee: University of Delaware, Newark, DE (US)

(21) Appl. No.: 14/075,368

(22) Filed: Nov. 8, 2013

Related U.S. Application Data
(60) Provisional application No. 61/724,586, filed on Nov. 9, 2012.

(51) Int. Cl. H01L 31/052; G02B 5/04

(52) U.S. Cl. CPC H01L 31/0524; G02B 5/045; H01L 31/0528
USPC 136/255; 359/615; 136/259

(57) ABSTRACT

Dispersive optical systems and methods are disclosed, as well as energy generation systems utilizing such systems in combination with photovoltaic cells. A dispersive optical system includes an optical element, a layer of high-dispersion microprisms, and a layer of low-dispersion microprisms. The optical element is configured to focus a light beam. The layer of high-dispersion microprisms is configured to refract the light beam. The layer of low-dispersion microprisms is configured to refract the light beam. The dispersive optical system is configured to optically concentrate and disperse input light incident thereupon into an output comprising a plurality of bands of light each having a different wavelength. A method of optical dispersion includes focusing a light beam with an optical element, refracting the light beam with a layer of high-dispersion microprisms, and refracting the light beam with a layer of low-dispersion microprisms.

### CROSS REFERENCE TO RELATED APPLICATIONS

This application claims priority to U.S. Patent Application No. 61/724,586, entitled “DISPERSIVE OPTICAL SYSTEMS AND METHODS AND RELATED ELECTRICITY GENERATION SYSTEMS AND METHODS,” filed on Nov. 9, 2012, the contents of which are incorporated herein by reference in their entirety.

### FIELD OF THE INVENTION

The invention relates generally to the field of optics, and more particularly, to dispersive optical systems and methods, particularly those for use with photovoltaic devices.

### BACKGROUND OF THE INVENTION

In conventional high-efficiency photovoltaic applications, photovoltaic cells may be subdivided into portions or regions that are optimized for a particular wavelength band of light. In other words, photovoltaic cells may include one portion that is most efficient at converting blue light into energy, another portion that is most efficient at converting green light into energy, etc.

Conventionally, while photovoltaic cells may include these specialized regions, each of these regions nonetheless receives the full spectrum of light received by the photovoltaic cell. For example, some conventional photovoltaic cells include these regions stacked one on top of the other, so that the light beam must pass through each region sequentially. Systems and methods are desired that more efficiently utilize spectral separation of light beams for photovoltaic applications.

### SUMMARY OF THE INVENTION

Aspects of the present invention are directed to dispersive optical systems and methods.

In accordance with one aspect of the present invention, a dispersive optical system is disclosed. The dispersive optical system comprises an optical element, a layer of high-dispersion microprisms, and a layer of low-dispersion microprisms. The optical element is configured to focus a light beam. The layer of high-dispersion microprisms is configured to refract the light beam. The layer of low-dispersion microprisms is configured to refract the light beam. The dispersive optical system is configured to optically concentrate and disperse input light incident thereupon into an output comprising a plurality of bands of light each having a different wavelength.

In accordance with another aspect of the present invention, a method of optical dispersion is disclosed. The method comprises focusing a light beam with an optical element, refracting the light beam with a layer of high-dispersion microprisms, and refracting the light beam with a layer of low-dispersion microprisms. The focusing and refracting steps optically concentrate and disperse the light beam into an output comprising a plurality of bands of light each having a different wavelength.

### BRIEF DESCRIPTION OF THE DRAWINGS

The invention is best understood from the following detailed description when read in connection with the accompanying drawings, with like elements having the same reference numerals. When a plurality of similar elements are present, a single reference numeral may be assigned to the plurality of similar elements with a small letter designation referring to specific elements. When referring to the elements collectively or to a non-specific one or more of the elements, the small letter designation may be dropped. According to common practice, the various features of the drawings are not drawn to scale unless otherwise indicated. To the contrary, the dimensions of the various features may be expanded or reduced for clarity. Included in the drawings are the following figures:

FIG. 1 is a diagram illustrating an exemplary dispersive optical system in accordance with aspects of the present invention;

FIG. 2 is a cross-sectional diagram illustrating exemplary microprisms of the dispersive optical system of FIG. 1;

FIG. 3 is a diagram illustrating a perspective view of the rear surface of the dispersive optical system of FIG. 1;

FIG. 4 is a diagram illustrating an alternative optical element of the dispersive optical system of FIG. 1;

FIG. 5 is a diagram illustrating another alternative optical element of the dispersive optical system of FIG. 1;

FIG. 6 is a diagram illustrating another alternative optical element of the dispersive optical system of FIG. 1;

FIG. 7 is a diagram illustrating an exemplary solar power system incorporating the dispersive optical system of FIG. 1;

FIGS. 8A-8C are diagrams illustrating exemplary corrective optical elements for aligning the dispersive optical system of FIG. 1;

FIG. 9 is a flowchart illustrating an exemplary dispersive optical method in accordance with aspects of the present invention;

FIG. 10 is a diagram illustrating another exemplary dispersive optical system in accordance with aspects of the present invention;

FIG. 11 is a diagram illustrating an alternative optical arrangement of microprism layers for the dispersive optical system of FIG. 10;

FIGS. 12A and 12B are diagrams illustrating exemplary non-imaging optical components of the dispersive optical system of FIG. 10;

FIG. 13 is a diagram illustrating another exemplary dispersive optical system in accordance with aspects of the present invention;

FIG. 14A is a diagram illustrating another exemplary dispersive optical system in accordance with aspects of the present invention;

FIG. 14B is a diagram illustrating an exemplary microprism of the dispersive optical system of FIG. 14A;

FIGS. 15A-15C are diagrams illustrating another exemplary dispersive optical system in accordance with aspects of the present invention;

FIGS. 16A and 16B are diagrams illustrating an alternative optical element of the dispersive optical system of FIGS. 15A-15C; and

FIG. 17 is a diagram illustrating another alternative optical element of the dispersive optical system of FIG. 1.

### DETAILED DESCRIPTION OF THE INVENTION

The embodiments of the invention described herein relate to optically concentrating and dispersing a light beam into different wavelength bands. In the embodiments described herein, the light beam is optically dispersed in order to create an output having specific concentrated wavelength bands that are direct on to appropriate regions of a photovoltaic device, e.g., in order to enhance conversion efficiency of the photovoltaic device. While the embodiments of the present invention are described herein with respect to solar power systems, it will be understood that the disclosed systems and methods may be usable in other suitable applications including, for example, hyperspectral imaging, optical interconnection, optical sensing, or any other area that may benefit from precisely controlled optical dispersions of light beams.

The systems and methods described herein generally utilize one or several layers of dispersive elements such as microprisms to separate (or disperse) a beam of white light (e.g. sunlight) into its component wavelength bands. The microprisms are designed to be very small in size, so that they may be incorporated on the surface or inside of conventional optical components in photovoltaic systems without substantially changing the basic optical functionality or physical profile of the optical components. As long as there is a prismatic interface (preferably in an array configuration to reduce the form factor) between two mediums with different dispersion properties but similar refractive indexes, optical dispersion may be created without interfering the original optical functionality of the optical component/system and changing its physical profile.

The systems and methods described herein can be implemented in a concentrating photovoltaic system in which the dispersive optical components deliver spectrally spread sunlight onto laterally-positioned multi-bandgap photovoltaic cells, in order to cover the entire solar spectrum. By selecting the sizes and materials of the microprisms, the disclosed embodiments concentrate and direct each of the component wavelength bands of the sunlight in a particular and specific direction away from the optical components and toward the photovoltaic components. Because these specific directions are predetermined, the above systems and methods include specialized multi-bandgap photovoltaic cells, photodetectors or sensors having lateral regions positioned in areas optimized for the respective wavelength bands they will receive. In some embodiments, the photovoltaic cells, photodetectors or sensors for different wavelength bands may be positioned as concentric circular bands when the prismatic structures in the dispersion layers are configured to be in a concentric circular array, instead of a linear array. Thus, the exemplary embodiments described herein desirably increase conversion efficiency of photovoltaic devices by directing wavelength bands of light onto the photovoltaic regions that are most efficient at converting those wavelength bands to energy.

The output of the exemplary embodiments of the present invention is referred to herein as including a plurality of wavelength bands of light, with each band associated with a particular wavelength or wavelengths. As used herein, the term “band of light” refers to a light beam or a portion of a light beam that predominately includes light having wavelengths in a certain region (e.g., a light beam including predominately blue light”). The bands of light discussed herein may nonetheless include other wavelengths of light in smaller amounts. Additionally, the term “band of light” does not necessarily refer to a specific, separate light beam, but may refer to a portion of a light beam that predominately includes the light having the wavelength of interest, which may be directly adjacent another portion of the light beam corresponding to a different wavelength.

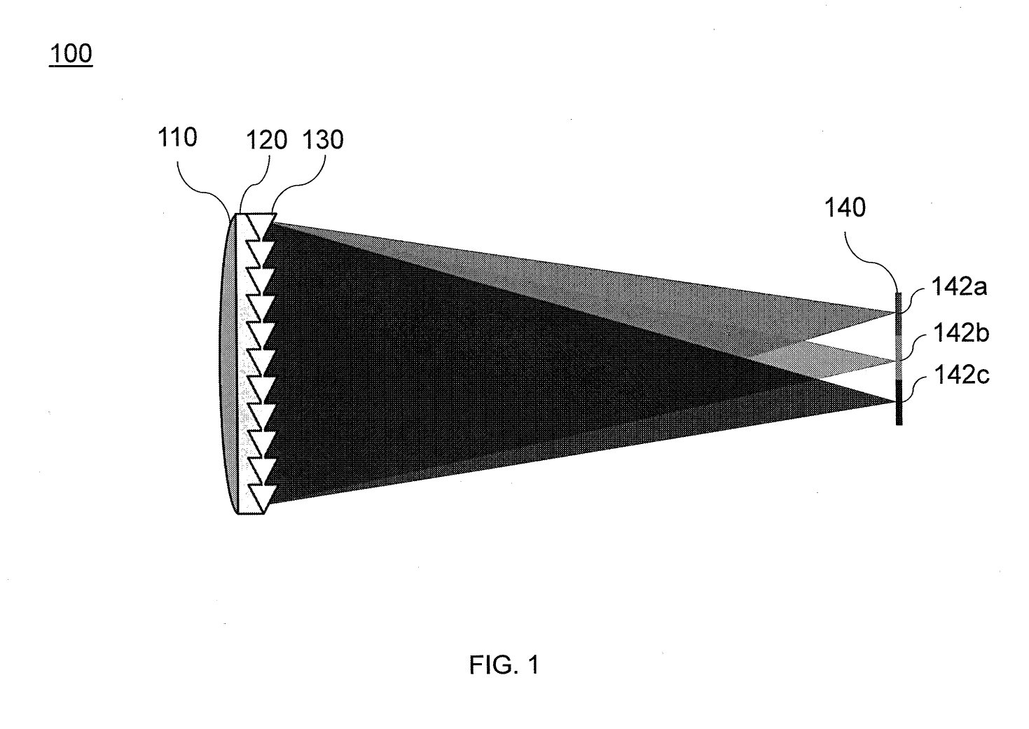

Referring now to the drawings, FIGS. 1-7 illustrate an exemplary dispersive optical system 100 in accordance with aspects of the present invention. Dispersive optical system 100 may be usable as part of a solar power system. As a general overview, dispersive optical system 100 includes an optical element 110, a layer of high-dispersion microprisms 120, and a layer of low-dispersion microprisms 130. Additional details of dispersive optical system 100 are described herein.

Optical element 110 is configured to focus a beam of light. In an exemplary embodiment, optical element 110 is a refractive lens, as shown in FIG. 1. However, optical element 110 is not so limited. Optical element 110 may be any optical element adapted to focus light (e.g. by refraction or reflection). Suitable optical elements for use as optical element 110 will be known to one of ordinary skill in the art from the description herein.

Microprism layers 120 and 130 are configured to disperse and refract the beam of light. It is desirable that the materials of microprism layers 120 and 130 at their prismatic interface have different dispersion properties (i.e., Abbe numbers), but similar refractive indices at the central operating wavelength. The prismatic interface is formed between two prism layers, or between one prism layer and the embedding optical component, as described below. Multiple prismatic interfaces may be used as necessary to achieve desired optical dispersion and beam deviation. In an exemplary embodiment, layer 120 comprises a layer of high-dispersion microprisms, and layer 130 comprises a layer of low-dispersion microprisms. As used herein, the “dispersion” of a microprism refers to the variance in refractive index of a material as a function of the wavelength of the light refracted. A material's dispersion may be measured by its Abbe number, or V-number, which is defined as:

$${V}_{d} = \frac{{n}_{d} - 1}{{n}_{F} - {n}_{C}}$$

where n_{d}, n_{F}, and n_{C} are the refractive indices of the material at the helium d line (5875.618 Å, yellow), the hydrogen F line (4861.327 Å, blue), and the hydrogen C line (6562.816 Å, red) from the Fraunhofer lines, respectively. The V-number of a material effectively represents the ratio of the basic refraction (n_{d}−1) to the dispersion (Δn=n_{F}−n_{C}) of the material. Therefore, as used herein, a high-dispersion material is a material having a relatively low V-number (e.g., polycarbonate), and a low-dispersion material is a material having a relatively high V-number (e.g., acrylic). An exemplary low-dispersion material for use with the present invention is poly(methyl methacrylate) (PMMA) with a V-number of ˜57.4; an exemplary high-dispersion material for use with the present invention is SF-57 glass (V-number=˜23.83) and polycarbonate (V-number=˜29.9). Other suitable high-dispersion and low-dispersion materials will be known to one of ordinary skill in the art from the description herein.

Generally, those of skill in the art may consider a material to be a low-dispersion material if it has a V-number greater than or equal to about 50, and a high dispersion material if it has a V-number less than about 50. As used herein, reference to “high dispersion microprisms” may refer to a first set of microprisms that have relatively lower V-numbers than a second set of “low-dispersion microprisms” having relatively higher V-numbers than the first set. In general, any combination of relatively higher dispersion microprisms and relatively lower dispersion microprisms may comprise an operative embodiment, regardless of V-numbers, so long as the relatively higher dispersion microprisms create spectral dispersion and the relatively lower dispersion microprisms cancel or direct in a desired direction any deviation from the propagation direction created by the relatively higher dispersion microprisms while maintaining a degree of spectral dispersion, such that the combination sufficiently directs the different wavelengths of light onto different target areas, as desired by a specific application.

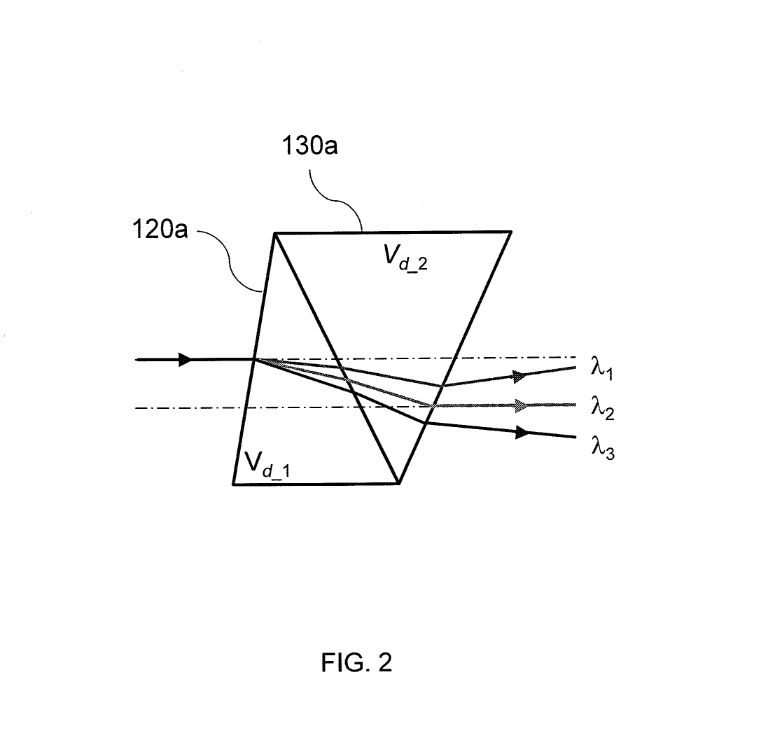

The function of microprism layers 120 and 130 will now be explained with reference to FIG. 2. FIG. 2 illustrates a pair of exemplary microprisms including a high-dispersion microprism 120a and a low-dispersion microprism 130a. When white light (e.g. sunlight) enters microprism 120a, the beam is dispersed into approximate wavelength bands, and is deviated from its original propagation direction. When the dispersed beam enters microprism 130a, the overall deviation of the beam is cancelled out or towards a desired direction, while approximately maintaining the spectral dispersion caused by microprism 120a. As a result, when the beam exits the microprisms, the beam has been dispersed into approximate wavelength bands without a change in its direction of propagation or steered towards a desired direction. The shape and materials of microprisms 120a and 130a may be selected to control the degree of dispersion and the distance the beam is shifted from its original axis and direction of propagation. The embodiments of the present invention combine multiple prisms with different refractive characteristics and geometric structures in order to produce a desired dispersion (e.g. corresponding to the layout of a laterally-positioned multi-bandgap photovoltaic cell) without deviating the beam (i.e. diverting the beam from its axis).

It will be understood by one of ordinary skill in the art that the relative order of high-dispersion and low dispersion microprisms shown in FIG. 2 is not intended to be limited. In other words, the layer of low-dispersion microprisms 130 may be placed in front of or behind the layer of high-dispersion microprisms 120 (relative to the direction of propagation of the light beam) without departing from the scope of the invention. Additionally, while only a single layer of high-dispersion microprisms 120 and low-dispersion microprisms 130 is shown in the accompanying drawings, it will be understood that dispersive optical system 100 may include a plurality of layers of high-dispersion microprisms 120, low-dispersion microprisms 130, or both, as necessary to direct the wavelength bands of light to the appropriate destinations.

In an exemplary embodiment, microprism layer 120 is formed directly on a rear surface of optical element 110, as shown in FIG. 1. Forming one of microprism layers 120 and 130 directly on the rear surface of optical element 110 desirably minimizes the thickness of dispersive optical system 100. The microprisms in layers 120 and 130 desirably have a thickness (i.e. in the direction of propagation of the light beam) in the range of a few microns to several millimeters, in order to achieve low-cost, high-precision fabrication (e.g., plastic molding) and a thin physical profile. In an exemplary embodiment, the microprisms have a thickness of no greater than 50 microns. This small thickness may be achieved through the use of the high-dispersion and low-dispersion materials described above. Microprism layers 120 and 130 may be formed on optical element 110, for example, by lithography, molding, etching, or machining.

As shown in FIG. 1, when microprism layer 120 is formed on the rear surface of optical element 110, microprism layer 130 may be formed directly on the rear surface of microprism layer 120. When the order of microprism layers is reversed, as described above, microprism layer 120 may be formed directly on the rear surface of microprism layer 130.

As set forth above, the optical element may be fabricated by molding, photo-lithography, etching, or machining. After the optical element is fabricated, the micro-prism layers may be fabricated by lithography, molding, etching, or machining. The optical element and micro-prism layers may then be bonded together using, e.g., optical adhesives.

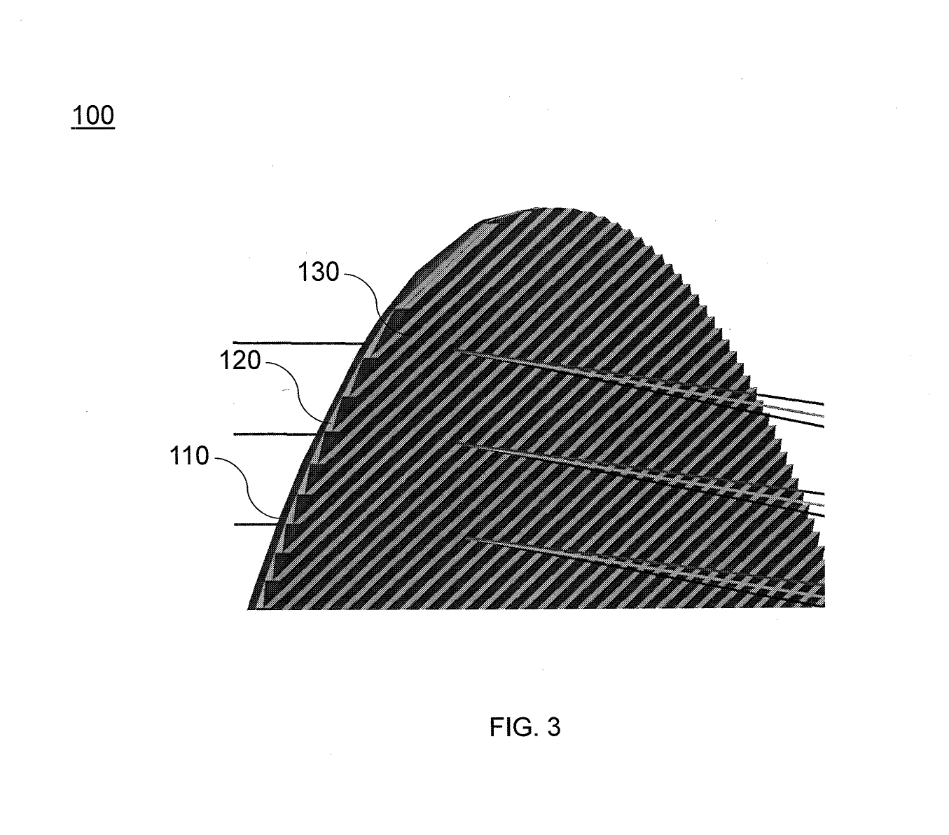

In this embodiment, microprism layers 120 and 130 comprise an array of microprisms, as shown in FIG. 3. Each microprism in the array extends linearly across the rear surface of optical element 110. Accordingly, the microprisms in layers 120 and 130 have a substantially constant cross-sectional shape (best shown in FIG. 1) along the entire rear surface of optical element 110. The microprisms in layers 120 and 130 desirably have a width (i.e. in the direction perpendicular to the direction in which they extend) in the range of a few microns to several millimeters. In an exemplary embodiment, the microprisms have a width of no greater than 150 microns. Microprism layers 120 and 130 may have a length such that they cover substantially all of the rear surface of optical element 110, e.g., from 1-25 mm. In an array design, while multiple optical elements 110 (e.g., micro- or mini-lenses) are arrayed in, e.g., a rectangular or hexagonal grid, the microprism layers 120 and 130 may have a length such that they cover substantially the entire rear surface of the arrayed elements. In another embodiment, the microprism layers may be formed at the curved surface of optical element 110. The microprisms in layers 120 and 130 may have varying cross-sectional shapes along the surface. In some other embodiments as set forth below, the dispersive lens comprises prismatic structures that are arrayed in a circular ring configuration (or a concentric circular array, instead of a one dimensional linear array), which radially disperse the light beam with different wavelengths into an output having concentric circular bands with different radii from the detector's center. Accordingly, the co-planar photovoltaic cells with different bandgap energies may be positioned in a ring configuration to collect the corresponding photons.

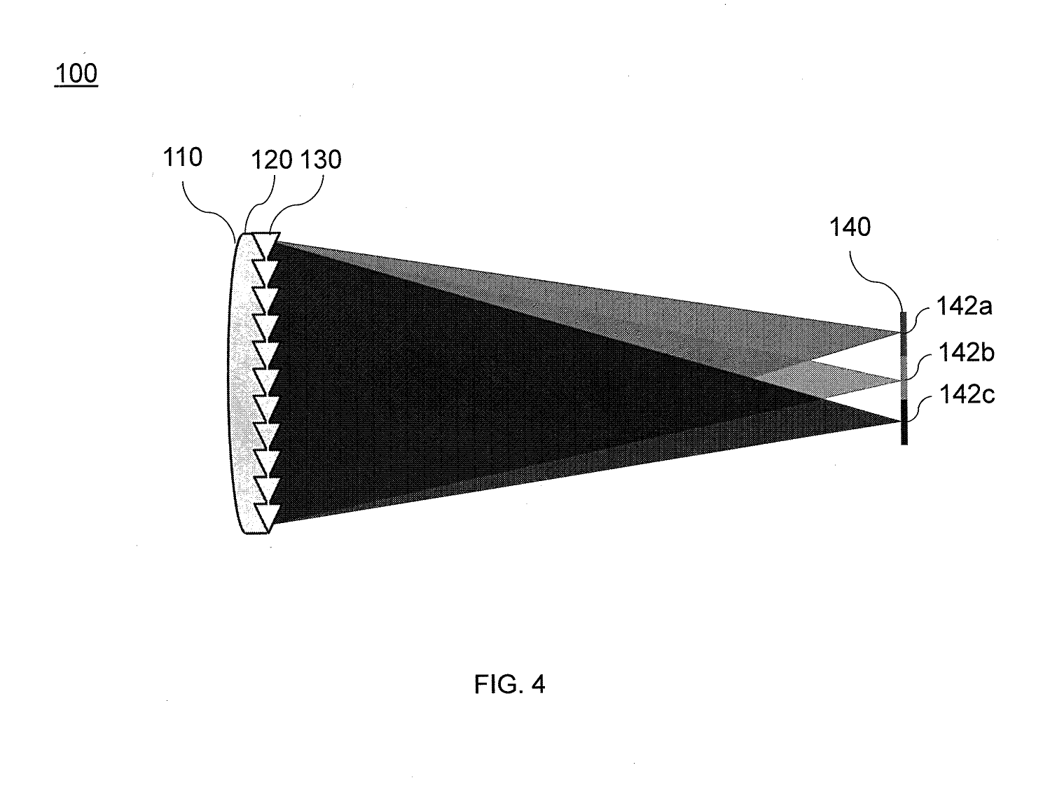

While optical element 110 and microprism layer 120 are illustrated as separate components in FIG. 1, the invention is not so limited. In an alternative exemplary embodiment, optical element 110 and microprism layer 120 (or microprism layer 130, when the orders are reversed) may be integrally formed with each other, as shown in FIG. 4. In this embodiment, optical element 110 comprises the same material (either high-dispersion or low-dispersion) as the microprism layer with which it is integrally formed. This embodiment of dispersive optical system 100 may be particularly desirable in order to simplify the manufacturing and assembly of dispersive optical system 100. With proper materials and configurations, the rear surface of microprism layer 130 may be configured flat (e.g., no tilted facets features). An alternative method is to fill the valleys at the rear surface of microprism layer 130 with another optical layer which has a flat rear surface.

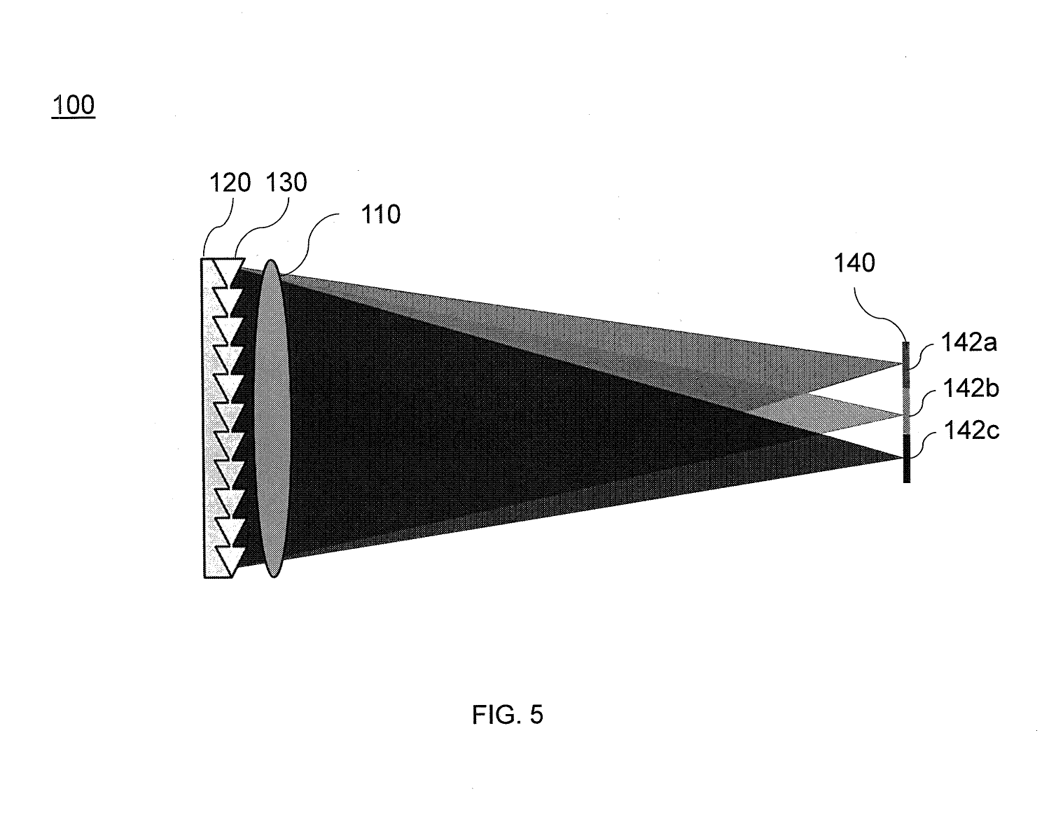

In another alternative exemplary embodiment, optical element 110 may be a separate component from microprism layers 120 and 130. As shown in FIG. 5, optical element 110 may be a refractive lens positioned rearward of microprism layers 120 and 130. This embodiment of dispersive optical system 100 may be particularly desirable in order to simplify removal and replacement of sub-components of dispersive optical system 100.

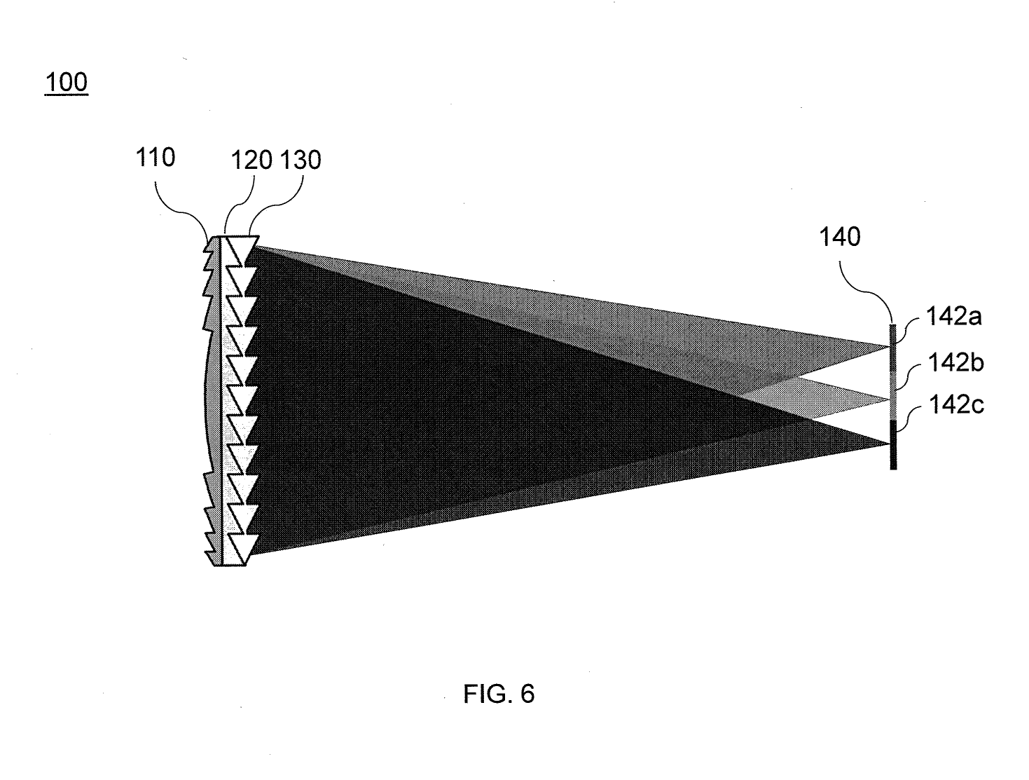

In a particularly preferable embodiment, optical element 110 comprises a Fresnel lens, as shown in FIG. 6. It may be preferable to use a Fresnel lens as optical element 110 in order to minimize the overall thickness of dispersive optical system 100. As set forth above, microprisms in layers 120 and 130 desirably have a small thickness, e.g, in the range of a few microns to several millimeters. By combining these thin microprisms with a Fresnel lens, the overall thickness of dispersive optical system 100 may be made very compact. In an exemplary embodiment, the combined thickness of optical element 110 (as a Fresnel lens) and microprism layers 120 and 130 is no greater than 250 microns.

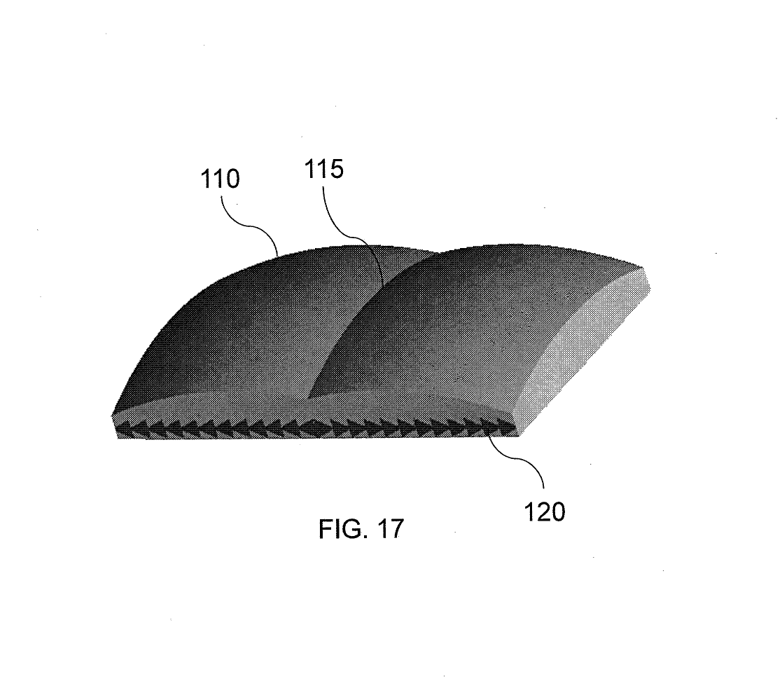

In still another alternative exemplary embodiment, optical element 110 comprises a decentered optical concentrator, as shown in FIG. 17. In particular, optical element 110 may be a spherical or aspherical lens that is split and decentralized away from the element's mechanical center axis (or optical axis) so that the new lens surface is formed by combining shifted lenses, resulting in split or spread focal spots. This may result in the formation of one or more new optical axes in the optical element. The arrays of microprisms may then be formed around the one or more new optical axis of the optical element, as explained below. Forming optical element 110 as a decentered lens may be desirable in order to compensate for beam deviation caused by microprism layer 120, and/or to recombine beams and thus enhance dispersion capability and precision.

As shown in FIG. 17, optical element 110 is a linearly decentered, forming a bisecting edge 115 along a center line of the lens, resulting in one-dimensional spectrum splitting. For this optical element 110, microprisms 120 are linearly arrayed along optical element 110 parallel to bisecting edge 115, with opposite orientations on opposite sides of the edge 115, as shown in FIG. 17.

Dispersive optical system 100 is not limited to the above described components, but may include alternative or additional components, as would be understood by one of ordinary skill in the art.

For one example, one or more grating layers may be added on the surfaces of the described components to enhance the dispersion. Suitable gratings for use with the present invention will be known to one of ordinary skill in the art.

For another example, dispersive optical system 100 may include a receiving element. In an exemplary embodiment, the receiving element is a photovoltaic cell 140. Photovoltaic cell 140 is positioned to receive the light beam from either optical element 110 or one of microprism layers 120 and 130 (depending on their respective order), as shown in FIG. 1. Suitable photovoltaic cells for use as photovoltaic cell 140 will be known to one of ordinary skill in the art from the description herein. In other embodiments, the receiving element may be other suitable components of optical systems, including, for example, optical signal receivers, optical fibers, or optical waveguides.

A particularly suitable photovoltaic cell will now be described that is intended to optimally utilize the dispersed optical beam generated by dispersive optical system 100. In an exemplary embodiment, photovoltaic cell 140 comprises a plurality of regions (or independent sub-cells) 142a, 142b, 142c, each of which are optimized for converting a particular wavelength band of light into energy. The design of a photovoltaic region that is optimized for a particular wavelength band of light will be understood by one of ordinary skill in the art. For example, region 142a may be optimized for converting relatively low energy photons (e.g., from 350 nm to 850 nm) to energy; region 142b may be optimized for converting relatively middle energy photons (e.g., from 850 nm to 1127 nm) to energy; and region 142c may be optimized for converting relatively high energy photons (e.g., from 1127 nm to 1771 nm) to energy.

In this embodiment, region 142a is optimized for converting relatively low energy photons into electrical energy (e.g. visible light); region 142b is adjacent region 142a and is optimized for converting relatively middle energy photons into electrical energy (e.g. near-infrared light); region 142c is adjacent region 142b and is optimized for converting relatively high energy photons into electrical energy (e.g. short-wavelength infrared light).

The arrangement and sizes of regions 142a, 142b, 142c are selected (taking into account a predetermined focal distance, e.g., ranging from several to tens of millimeters) to correspond to the dispersed beam emitted from optical element 110 and microprism layers 120 and 130. In this way, the photovoltaic cell 140 may be positioned such that region 142a receives a band of light from optical element 110 or microprism layers 120 or 130 that predominately includes its desired wavelength band (i.e., low energy photons); region 142b receives a band of light from optical element 110 or microprism layers 120 or 130 that predominately includes its desired wavelength band (i.e., middle energy photons); and region 142c receives a band of light from optical element 110 or microprism layers 120 or 130 that predominately includes its desired wavelength band (i.e., high energy photons).

While regions 142a, 142b, 142c are described above as discrete cells, it will be understood that the invention is not so limited. Photovoltaic cell 140 may have a continuously varying bandgap across the cell region to form regions 142a, 142b, 142c. The cell 140 may then be positioned such that it receives photons with corresponding energies from the dispersive element across the continuously varying bandgap.

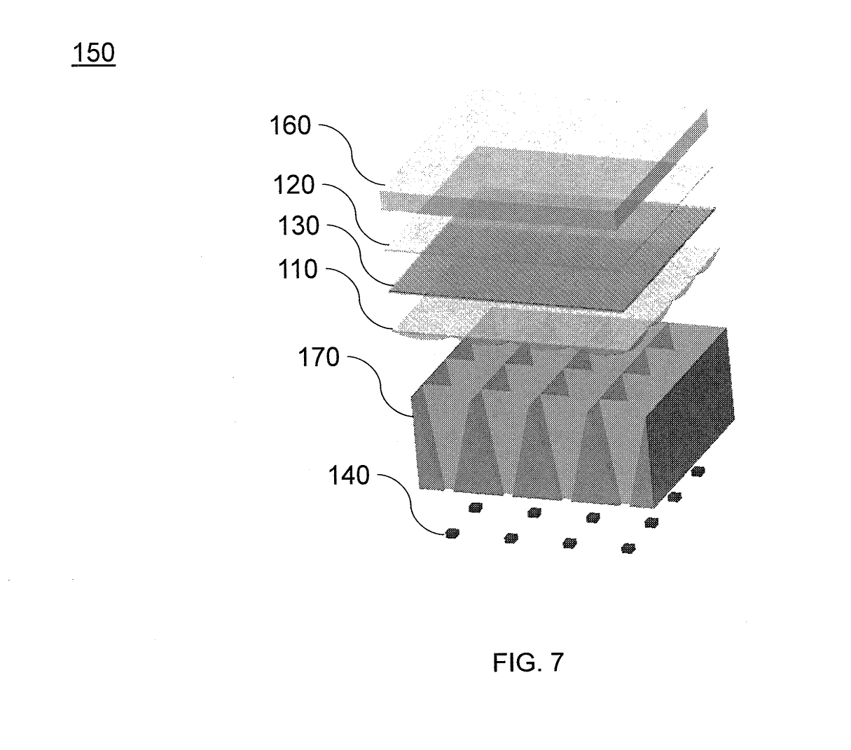

As described above, dispersive optical system 100 may be usable as part of a solar power system. An exploded view of an exemplary solar power system 150 incorporated dispersive optical system 100 is illustrated in FIG. 7. In this embodiment, it may be expected that the solar power system will include solar power panels, each of which will comprise a plurality of photovoltaic cells. Accordingly, in solar power system applications, it may be desirable that each photovoltaic cell include its own dispersive optical system 100 to focus sunlight independently onto the respective photovoltaic cell.

As shown in FIG. 7, solar power system 150 comprises a front transparent plate 160, such as but not limited to a glass plate. Transparent plate 160 forms an outer layer of solar power system 150, and may be used to provide protection to the optical components of solar power system 150. Beneath transparent plate 160 are positioned optical element 110 and microprism layers 120 and 130. It will be understood by one of ordinary skill in the art that the relative order of the components of dispersive optical system 100 shown in FIG. 7 is illustrative, and is not intended to be limiting, as described above. Beneath optical element 110 is frame 170, which defines a plurality of cavities for respective photovoltaic cells 140. Frame 170, which in an exemplary embodiment may be a metal frame, but is not limited to any particular materials of construction, is desirable in order to isolate the light that is concentrated and dispersed by each dispersive optical system 100. The walls of frame 170 may also comprise reflective material, in order to enhance light collection. Frame 170 may be particularly useful in order to prevent interference caused by light from separate dispersive optical systems 100, and/or to enhance light collection by making the side wall surfaces reflective, and/or to provide mechanical support.

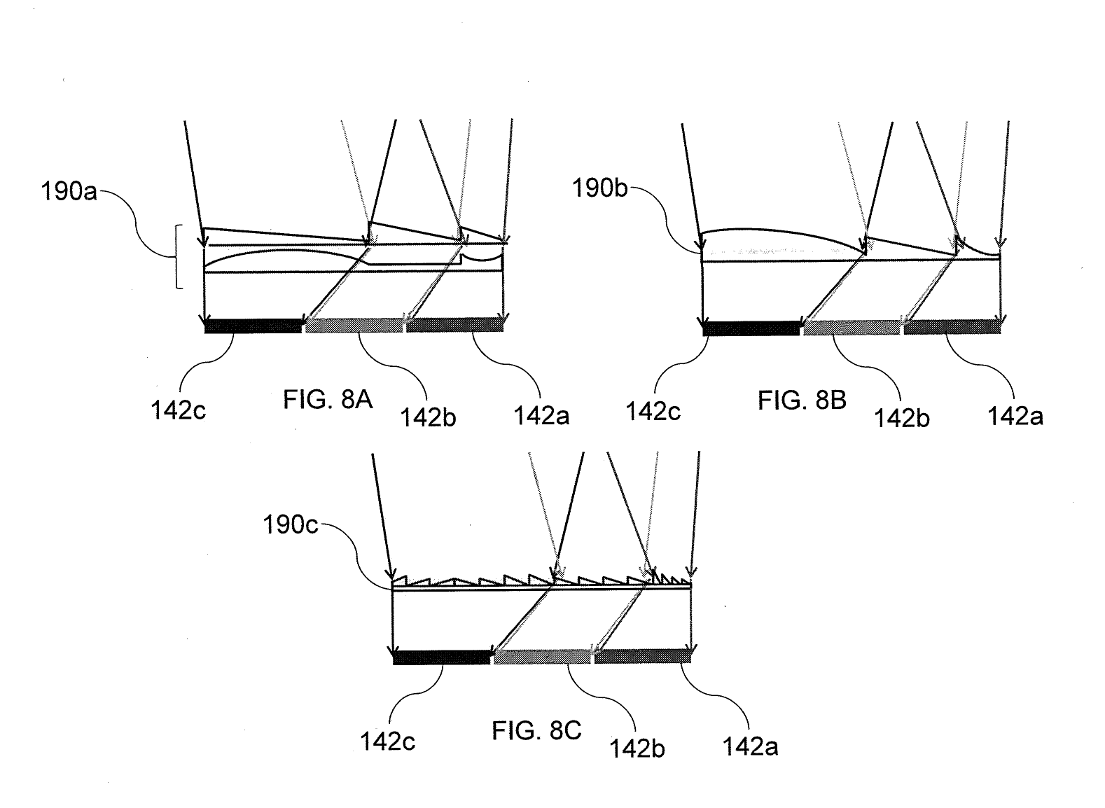

FIGS. 8A-8C illustrate exemplary corrective optical elements 190a, 190b, 190c for aligning the dispersive optical system in accordance with aspects of the present invention. The elements may be used when a mismatch exists between the spectrally dispersed light from dispersive optical system 100 and the appropriate regions 142a, 142b, 142c of photovoltaic cell 140. In an exemplary embodiment, corrective optical element 190a comprises a refractive layer and a separate deflective layer, as shown in FIG. 8A. In another exemplary embodiment, corrective element 190b comprises a combined refractive and deflective layer, as shown in FIG. 8B. In yet another exemplary embodiment, corrective element 190c comprises a compact refractive and deflective layer in which the surfaces are collapsed on a single plane (similar in structure to a Fresnel lens). The embodiment of FIG. 8C may be particularly suitable for achieving a compact, thin dispersive optical system 100. The selection of suitable deflective and refractive surfaces for aligning the wavelength bands with corresponding regions 142a, 142b, 142c will be understood by one of ordinary skill in the art from the description herein. It will further be understood that in an alternative embodiment, PV cell 140 may be specially designed such that corrective optical elements 190a, 190b, 190c are unnecessary.

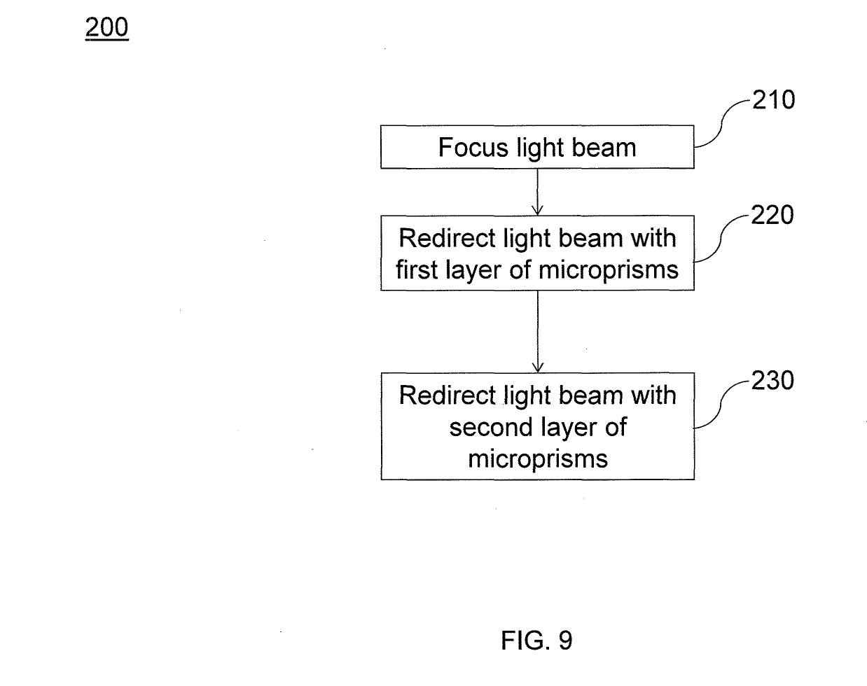

FIG. 9 illustrates an exemplary dispersive optical method 200 in accordance with aspects of the present invention. Dispersive optical method 200 may be performed by a solar power system. As a general overview, dispersive optical method 200 includes focusing a light beam, refracting the light beam with a first microprism, and refracting the light beam with a second microprism. Additional details of dispersive optical method 200 are described herein with respect to dispersive optical system 100.

In step 210, a light beam is focused. In an exemplary embodiment, first optical element 110 focuses an incident light beam (e.g., sunlight).

In step 220, the light beam is redirected and dispersed with a first layer of microprisms. In an exemplary embodiment, the layer of high-dispersion microprisms 120 refract the light. In doing so, microprisms 120 disperse the light into approximate wavelength bands, and deviate the light from its original propagation direction. The layer of microprisms 120 may be formed directly on a rear surface of optical element 110.

In step 230, the light beam is redirected and dispersed with a second layer of microprisms. In an exemplary embodiment, the layer of low-dispersion microprisms 130 refract the light. In doing so, microprisms 130 cancel out the deviation of the light beam or steer the beam towards a desired direction, while maintaining the spectral dispersion caused by microprisms 120. As a result, when the beam exits the microprisms, the beam has been dispersed into an output having approximate wavelength bands without a change in its direction of propagation, or while steering it towards a desired direction. The layer of microprisms 130 may be formed directly on a rear surface of the layer of microprisms 120.

While the steps of method 200 are recited in a particular order, it will be understood by one of ordinary skill in the art that the order in which the steps are recited is not limiting. For one example, the step of refracting the light beam with low-dispersion microprisms may be performed prior to the step of refracting the light beam with high-dispersion microprisms. For another example, when the embodiment of dispersive optical system 100 shown in FIG. 5 is used, one of ordinary skill in the art will understand that the steps of refracting the light beam with microprisms will come before the focusing step.

Dispersive optical method 200 is not limited to the above described steps, but may include alternative or additional steps, as would be understood by one of ordinary skill in the art.

For one example, optical element 110 and layer of microprisms 120 or 130 may be integrally formed into a single component. Thus, in an exemplary embodiment, the focusing step and one of the refracting steps are performed by the single component.

For another example, dispersive optical method 200 may include a photovoltaic cell. Thus, in an exemplary embodiment, the light beam optical element 110 or microprism layers 120 and 130 is received with photovoltaic cell 140. As described above, photovoltaic cell 140 may include a plurality of regions or sub-cells 142a, 142b, 142c, each of which are optimized for converting a particular wavelength band of light into energy. Thus, in this embodiment, the photovoltaic cell 140 is positioned such that region 142a receives a band of light from optical element 110 or microprism layers 120 or 130 that predominately includes its desired wavelength band (i.e., relatively low energy photons); region 142b receives a band of light from optical element 110 or microprism layers 120 or 130 that predominately includes its desired wavelength band (i.e., relatively middle energy photons); and region 142c receives a band of light from optical element 110 or microprism layers 120 or 130 that predominately includes its desired wavelength band (i.e., relatively high energy photons).

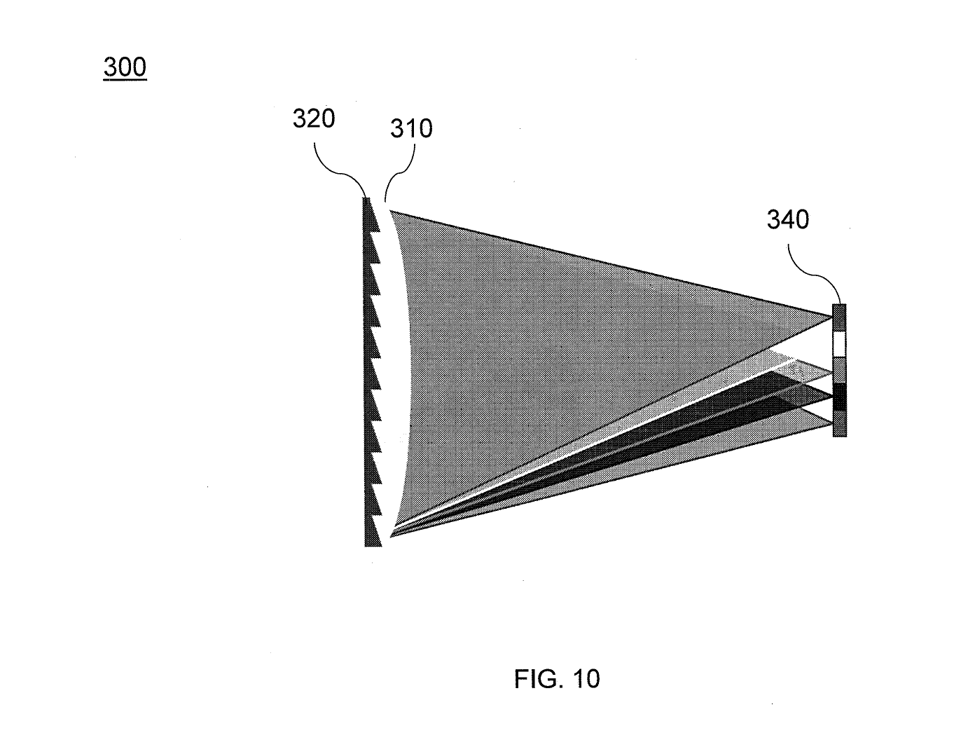

FIGS. 10-12B illustrate an exemplary dispersive optical system 300 in accordance with aspects of the present invention. Dispersive optical system 300 may be usable as part of a solar power system. As a general overview, dispersive optical system 100 includes an optical element 310 and a layer of microprisms 320. Additional details of dispersive optical system 300 are described herein.

Optical element 310 is configured to focus a beam of light. In an exemplary embodiment, optical element 310 is a refractive lens, as shown in FIG. 10. However, optical element 310 may comprise any of the optical elements described above with respect to optical element 110.

Microprism layer 320 is configured to disperse and refract the beam of light. Microprism layer 320 may include the same shape, size, and materials of any of the layers of microprisms described above with respect to layers 120 and 130. In an exemplary embodiment, layer 320 contains a plurality of high dispersion, low V-number microprisms that spectrally disperse light; optical element 310 comprises a low dispersion, high V-number material that cancels the beam deviation (or steers the beam towards a desired direction) while approximately preserving the dispersion and concentrates the light. Alternatively, layer 320 may contain low dispersion, high V-number microprisms while optical element 310 comprises high dispersion, low V-number material. Microprism layer 320 is provided either on the front surface of optical element 310, as shown in FIG. 10, or embedded within optical element 310.

Another method for making the dispersive optical system comprises: Fabricating the optical element and one of the micro-prism array 310 by molding, photo-lithography, etching, or machining; forming the other micro-prism array 320 by directly filling the valleys of the first micro-prism array with a different optical material and curing to optical material's operational condition (many plastic materials can be cured from a liquid form to a solid or semi-solid form, e.g., PDMS).

It will be understood by one of ordinary skill in the art that the relative order of optical layer 310 and microprism layer 320 shown in FIG. 10 is not intended to be limited. In other words, the layer of microprisms 320 may be positioned in front of or behind the optical component 310 (relative to the direction of propagation of the light beam) without departing from the scope of the invention. Additionally, while only a single layer of microprisms 320 is shown in the accompanying drawings, it will be understood that dispersive optical system 300 may include a plurality of layers of microprisms 320, as necessary to direct the wavelength bands of light to the appropriate destinations. Still further, microprism layer 320 may be positioned on a curved surface of optical element 310 (such as a curved lens surface).

Dispersive optical system 300 is not limited to the above described components, but may include alternative or additional components, as would be understood by one of ordinary skill in the art.

For one example, one or more grating layers may be added on the surfaces of the described components to enhance the dispersion. Suitable gratings for use with the present invention will be known to one of ordinary skill in the art.

For another example, dispersive optical system 300 may include a receiving element. In an exemplary embodiment, the receiving element is a photovoltaic cell 340, as shown in FIG. 10. Suitable photovoltaic cells for use as photovoltaic cell 340 include any of the photovoltaic cells described above with respect to photovoltaic cell 140.

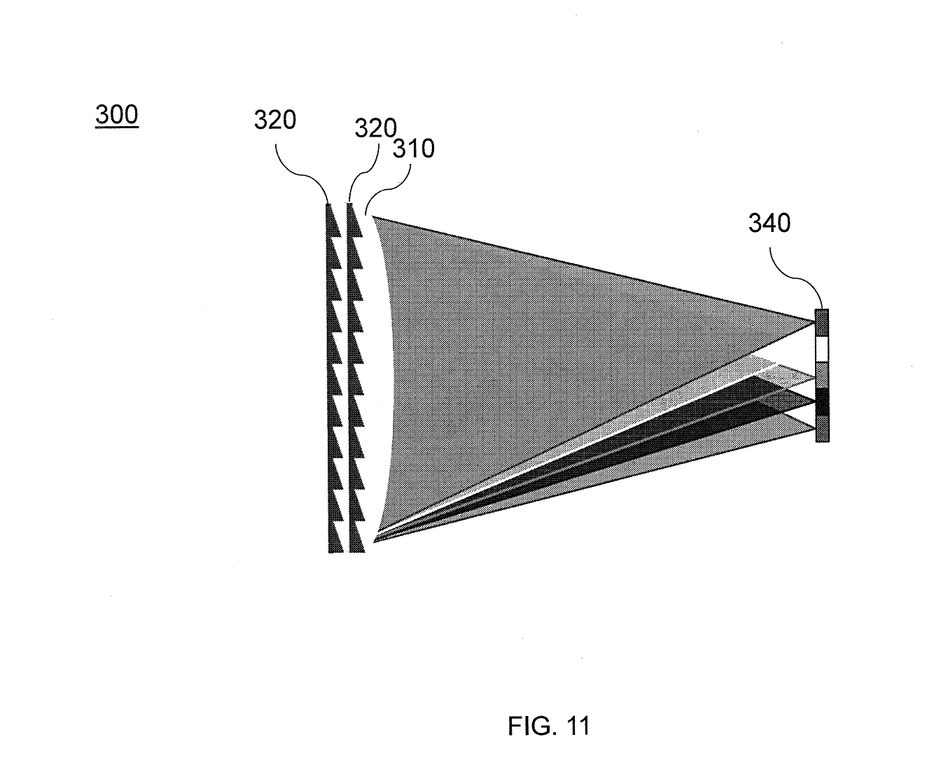

For still another example, dispersive optical system 300 may include multiple layers of microprisms 320 in order to enhance the overall chromatic dispersion. As shown in FIG. 11, dispersive optical system 300 includes a plurality of high dispersion, low V-number microprism layers 320 that spectrally disperse the incident light. Similarly, optical element 310 includes a low dispersion, high V-number material (formed in shapes corresponding to the microprisms) that create a prismatic interface with the microprism layers 320, and cancel the deviation of the incident light beam while approximately preserving the dispersion. One of the microprism layers 320 is formed on a surface of optical element 310, while another microprism layer 320 is embedded within optical element 310.

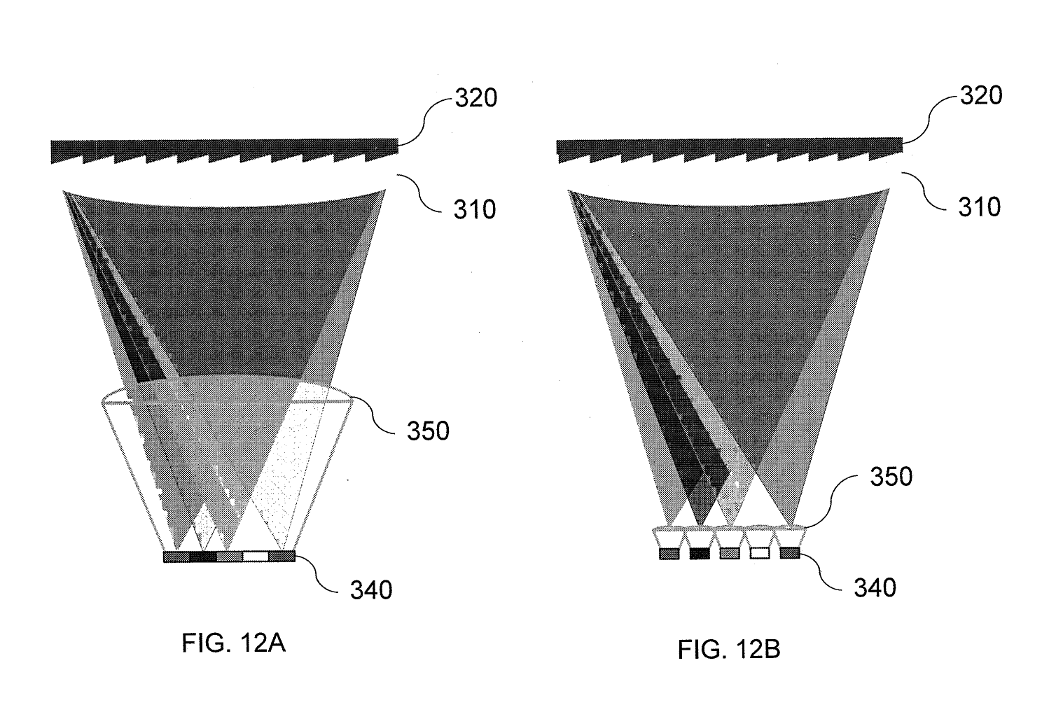

For yet another example, dispersive optical system 300 may include one or more non-imaging optical components 350 positioned between optical element 310 and photovoltaic cell 340, as shown in FIGS. 12A and 12B. Non-imaging optical components 350 may improve tolerance to misalignment of dispersive optical system 300 by concentrating or redirecting the spectrally dispersed beams leaving optical element 310 on the appropriate sections of photovoltaic cell 340. Suitable non-imaging optical components include, for example, a refractive lens, a plurality of microlenses, reflective facts or cones, and/or compound parabolic concentrators.

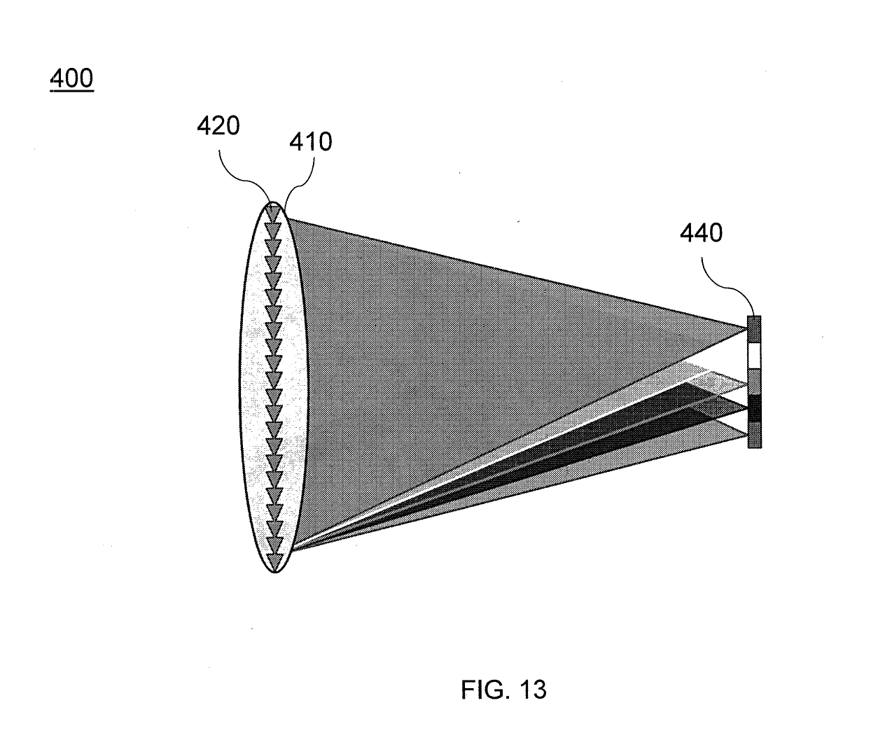

FIG. 13 illustrates an exemplary dispersive optical system 400 in accordance with aspects of the present invention. Dispersive optical system 400 may be usable as part of a solar power system. As a general overview, dispersive optical system 400 includes an optical element 410 and a layer of microprisms 420. Additional details of dispersive optical system 400 are described herein.

Optical element 410 is configured to focus a beam of light. In an exemplary embodiment, optical element 410 is a refractive lens, as shown in FIG. 13. However, optical element 410 may comprise any of the optical elements described above with respect to optical element 110.

Microprism layer 420 is configured to disperse and refract the beam of light. Microprism layer 420 may include the same shape, size, and materials of any of the layers of microprisms described above with respect to layers 120 and 130. In an exemplary embodiment, layer 420 contains a plurality of high dispersion, low V-number microprisms that spectrally disperse light; optical element 410 comprises a low dispersion, high V-number material that cancels the beam deviation (or steers the beam towards a desired direction) while approximately preserving the dispersion and concentrates the light. Alternatively, layer 420 may contain low dispersion, high V-number microprisms while optical element 410 comprises high dispersion, low V-number material. Microprism layer 420 is embedded within optical element 410, as shown in FIG. 13.

It will be understood by one of ordinary skill in the art that while only a single layer of microprisms 420 is shown in the accompanying drawings, dispersive optical system 400 may include a plurality of layers of microprisms 420, as necessary to direct the wavelength bands of light to the appropriate destinations.

Dispersive optical system 400 is not limited to the above described components, but may include alternative or additional components, as would be understood by one of ordinary skill in the art. For example, dispersive optical system 400 may include any of the components described above with respect to systems 100 and 300. In particular, dispersive optical system 400 may include a photovoltaic cell 440, as shown in FIG. 13.

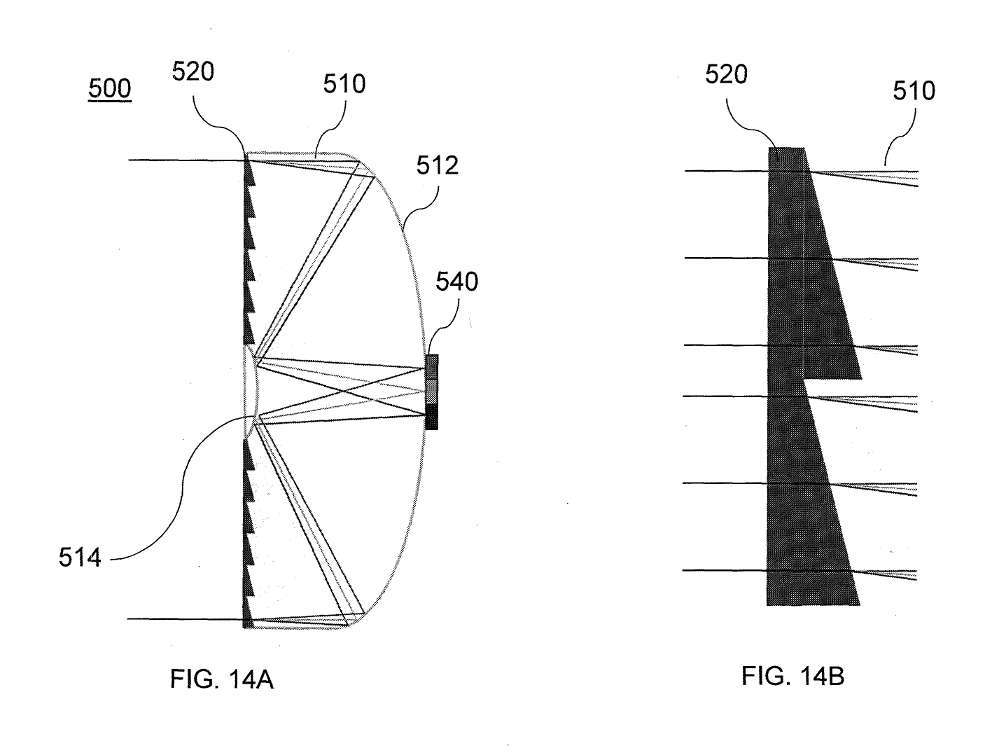

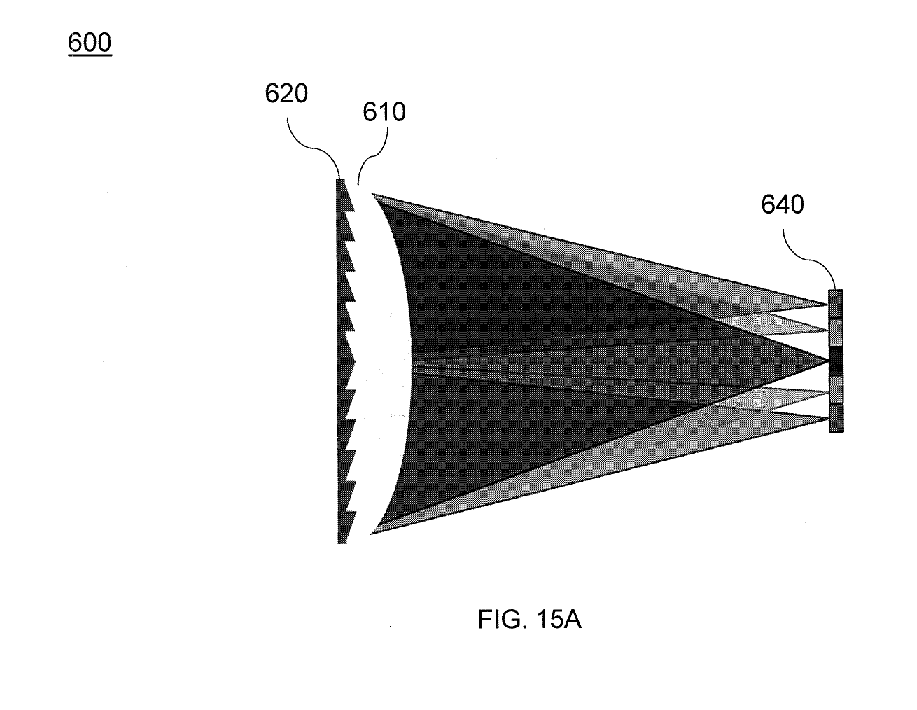

FIGS. 14A and 14B illustrate an exemplary dispersive optical system 500 in accordance with aspects of the present invention. Dispersive optical system 500 may be usable as part of a solar power system. As a general overview, dispersive optical system 500 includes an optical element 510 and a layer of microprisms 520. Additional details of dispersive optical system 500 are described herein.

Optical element 510 is configured to focus a beam of light. In an exemplary embodiment, optical element 510 is an optical concentrator having a back reflective surface 512 and a front reflective surface 514. The function of reflective surfaces 512 and 514 will be explained below. Reflective surfaces 512 and 514 may be formed, for example, by a conventional reflective coating material.

Microprism layer 520 is configured to disperse and refract the beam of light. Microprism layer 520 may include the same shape, size, and materials of any of the layers of microprisms described above with respect to layers 120 and 130. In an exemplary embodiment, layer 520 contains a plurality of high dispersion, low V-number microprisms that spectrally disperse light; optical element 510 comprises a low dispersion, high V-number material that cancels the beam deviation (or steers the beam towards a desired direction) while approximately preserving the dispersion and concentrates the light. Alternatively, layer 520 may contain low dispersion, high V-number microprisms while optical element 510 comprises high dispersion, low V-number material. Microprism layer 520 is provided either on the front surface of optical element 510, as best shown in FIG. 14B, or embedded within optical element 510.

When incident light contacts dispersive optical system 500, it is spectrally dispersed by microprisms 520 substantially as described above with respect to dispersive optical system 100. The spectrally dispersed light propagates within optical component 510 until it is reflected by reflective surface 512. Reflective surface 512 reflects the spectrally dispersed light within optical component 510 toward reflective surface 514. Reflective surface 514 reflects the spectrally dispersed light toward a rearward surface of optical component 510 that lacks the reflective surface 512.

It will be understood by one of ordinary skill in the art that while only a single layer of microprisms 520 is shown in FIG. 14B, dispersive optical system 500 may include a plurality of layers of microprisms 520, as necessary to direct the wavelength bands of light to the appropriate destinations. Still further, microprism layer 520 may be positioned on a curved surface of optical element 310 (such as a curved lens surface).

Dispersive optical system 500 is not limited to the above described components, but may include alternative or additional components, as would be understood by one of ordinary skill in the art. For example, dispersive optical system 500 may include any of the components described above with respect to systems 100 and 300. In particular, dispersive optical system 500 may include a photovoltaic cell 540, as shown in FIG. 132. Photovoltaic cell 540 is positioned to receive the spectrally dispersed light reflected by reflective surface 514, as shown in FIG. 14A.

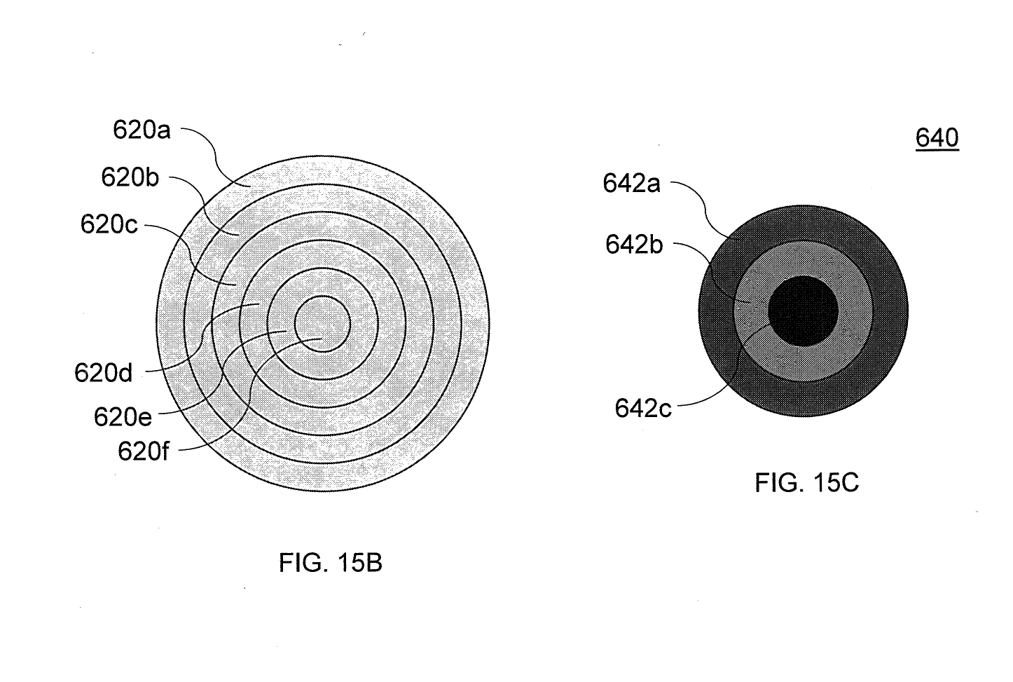

FIGS. 15A-15C illustrate an exemplary dispersive optical system 600 in accordance with aspects of the present invention. Dispersive optical system 600 may be usable as part of a solar power system. As a general overview, dispersive optical system 600 includes an optical element 610 and a layer of microprisms 620. Additional details of dispersive optical system 600 are described herein.

Optical element 610 is configured to focus a beam of light. In an exemplary embodiment, optical element 610 is a refractive lens, as shown in FIG. 15A. However, optical element 610 may comprise any of the optical elements described above with respect to optical element 110.

Microprism layer 620 is configured to disperse and refract the beam of light. Microprism layer 620 may have the same size and materials of any of the layers of microprisms described above with respect to layers 120 and 130. As shown in FIG. 15B, which provides a top view of system 600, microprism layer 620 comprises a layer of annular microprisms 620a-620f. Microprisms 620a-620f are desirably concentrically positioned around the central axis of optical element 610. In an exemplary embodiment, layer 620 contains a plurality of high dispersion, low V-number microprisms that spectrally disperse light; optical element 610 comprises a low dispersion, high V-number material that cancels the beam deviation (or steers the beam towards a desired direction) while approximately preserving the dispersion and concentrates the light.

It will be understood by one of ordinary skill in the art that the relative order of optical layer 610 and microprism layer 620 shown in FIG. 15A is not intended to be limited. In other words, the layer of microprisms 620 may be positioned in front of or behind the optical component 610 (relative to the direction of propagation of the light beam) without departing from the scope of the invention. Additionally, while only a single layer of microprisms 620 is shown in the accompanying drawings, it will be understood that dispersive optical system 600 may include a plurality of layers of microprisms 620, as necessary to direct the wavelength bands of light to the appropriate destinations. Still further, microprism layer 620 may be positioned on a curved surface of optical element 610 (such as a curved lens surface).

Dispersive optical system 600 is not limited to the above described components, but may include alternative or additional components, as would be understood by one of ordinary skill in the art.

For example, dispersive optical system 600 may include a receiving element. In an exemplary embodiment, the receiving element is a photovoltaic cell 640, as shown in FIGS. 15A and 15C. Suitable photovoltaic cells for use as photovoltaic cell 640 include any of the photovoltaic cells described above with respect to photovoltaic cell 140.

The shape of photovoltaic cell 640 is dictate by the orientation of microprisms 620a-620f in microprism layer 620. As shown in FIG. 15C, which provides a top view of photovoltaic cell 640, photovoltaic cell 640 comprises annular photovoltaic regions 642a-642c. Photovoltaic regions 642a-642c are desirably concentrically positioned around the central axis of optical element 610. In an exemplary embodiment, region 642a receives a band of light from optical element 610 or microprism layer 620 that predominately includes its desired wavelength band (i.e., relatively low energy photons); region 642b receives a band of light from optical element 610 or microprism layer 620 that predominately includes its desired wavelength band (i.e., relatively middle energy photons); and region 642c receives a band of light from optical element 610 or microprism layer 620 that predominately includes its desired wavelength band (i.e., relatively high energy photons).

The orientation/profile of the microprisms in microprism layer 620 shown in FIG. 15A is designed to direct the relatively high energy photons on to or in a ring close to the central axis of optical element 610 (corresponding to region 642c), and direct the relatively low energy photos in a ring farther from the central axis of optical element 610 (corresponding to region 642a). However, it will be understood by one of ordinary skill in the art that the orientation/profile of microprisms in layer 620 is not intended to be limited. For example, the orientation/profile of microprisms in microprism layer 620 may be reversed from that shown in FIG. 15A. In this embodiment, microprism layer 620 would direct the relatively low energy photons on to or in a ring close to the central axis of optical element 610 (corresponding to region 642c), and direct the relatively high energy photos in a ring farther from the central axis of optical element 610 (corresponding to region 642a). Accordingly, the regions 642a-642c of photovoltaic element 40 may be positioned based on both the shape and the orientation/profile of the microprisms in microprism layer 620.

While the microprisms 620a-620f of system 600 are illustrated annularly, it will be understood that the invention is not so limited. Microprisms in microprism layer 620 may be provided with any shape or configuration to achieve the desired dispersion patterns, e.g., for matching one or more photovoltaic cells.

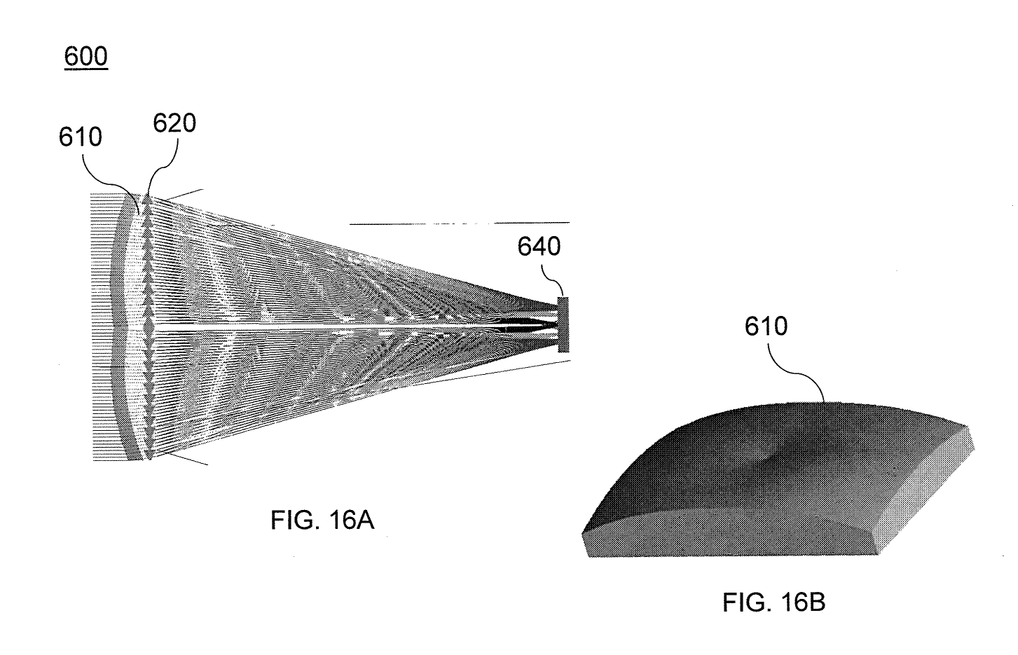

In an alternative exemplary embodiment, optical element 610 comprises a decentered optical concentrator, as shown in FIG. 16A. In particular, optical element 610 may be a spherical or aspherical lens that is split and decentralized away from the element's mechanical center axis (or optical axis) so that the new lens surface is formed by combining shifted lenses, resulting in split or spread focal spots. Forming optical element 610 as a decentered lens may be desirable in order to compensate for beam deviation caused by microprism layer 620, and/or to recombine beams and thus enhance dispersion capability and precision.

As shown in FIG. 16A, when optical element 610 comprises a decentered lens, the microprisms 620 on opposing sides of the center of optical element 610 have opposite orientations.

FIG. 16B shows an embodiment of a decentered optical element 610. In this embodiment, optical element 610 is a radially decentered, forming a toroidal lens that results in two-dimensional spectrum splitting. For this optical element 610, microprisms 620 are annularly arrayed along optical element 610 with their center at the mechanical center of optical element 610, i.e., the location of the decentering point.

### Example of the Invention

Simulations of the exemplary embodiment of dispersive optical system 100 illustrated in FIG. 6 have been performed to demonstrate the operation of the invention. The simulations were performed using a three-dimensional ray-tracing software that employed a Monte Carlo process, in which rays are launched randomly in location and direction within pre-defined ranges. Using a light source with half-degree divergence angle (simulating the solar disk) and AM1.5G spectrum, and assuming no Fresnel reflection loss at the optical surfaces, an optical transmission of over 97% was obtained, with the majority of the loss contributed by the edge effect of the micro-prisms. Such losses are dependent on the density of the micro-prisms (larger prisms result in higher total transmission) and thus a trade-off exists between the thickness (weight) and optical loss of the optical system. The simulated design produced efficiently dispersed spectrum spreading over an example 5 mm receiver region. Commercially available materials such as PMMA lenses with a similar size for solar concentrators have a transmission of ˜92%, which can be improved significantly by anti-reflection (AR) coatings. Therefore, an optical transmission of >90% is expected for this design employing a Fresnel lens front surface and appropriate AR coatings. Simulation of a configuration similar to FIG. 4 yielded an optical transmission of ˜94% when ¼ wave AR coating applied on front and back sides of the dispersive lens.

Additionally, simulations have been performed to estimate the ultimate performance in space-based applications for the above-described embodiment of the present invention. For these simulations, a total thickness of the dispersive optical system of approximately 200 microns was used, including approximately 150 micron average thickness of PMMA (at 1.18 g/cm³) and approximately 20 micron average thickness of SF-57 glass (at 5.51 g/cm³). To first order, this is equivalent to approximately 120 microns of regular glass (e.g. NBK7, with density 2.5 g/cm³). Assuming a total thickness of 200 microns for the encapsulation layers and mechanical supports with glass density, the total equivalent thickness in glass is approximately 327.5 microns. Assuming that the photovoltaic cell has a conversion efficiency of 35% and the optical efficiency of the ultra-compact dispersive lens is 90%, under the assumed 1366.1W/m² solar irradiance in space, the projected performance is: (1366.1*0.35*0.9)/((327.5e-6)*2500)=525.58 W/kg.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A dispersive optical system comprising:
an optical element configured to focus a light beam;
a layer of high-dispersion microprisms configured to refract the light beam; and
a layer of low-dispersion microprisms configured to refract the light beam,
the dispersive optical system configured to optically concentrate and disperse input light incident thereupon into an output comprising a plurality of bands of light each having a different wavelength.

2. The dispersive optical system of claim 1, wherein the optical element comprises one of a refractive lens, a reflective curved surface, or a grating.

3. The dispersive optical system of claim 2, wherein the optical element comprises a Fresnel lens.

4. The dispersive optical system of claim 3, wherein the combined thickness of the optical element and the layers of microprisms is no greater than 250 microns.

5. The dispersive optical system of claim 2, wherein the optical element comprises a decentered optical lens.

6. The dispersive optical system of claim 1, wherein one of the layers of microprisms is formed directly on a rear surface of the optical element.

7. The dispersive optical system of claim 6, wherein the other one of the layers of microprisms is formed directly on a rear surface of the one of the layers of microprisms.

8. The dispersive optical system of claim 6, wherein the one of the layers of microprisms comprises an array of microprisms with each microprism extending linearly across the rear surface of the optical element.

9. The dispersive optical system of claim 1, wherein the optical element is integrally formed with and comprises the same material as one of the layers of microprisms.

10. The dispersive optical system of claim 1, wherein at least one of the layers of microprisms is embedded within the optical element.

11. The dispersive optical system of claim 1, wherein the layers of microprisms comprise microprisms having a thickness of no greater than 50 microns.

12. The dispersive optical system of claim 1, wherein the layers of microprisms comprise microprisms having a width of no greater than 150 microns.

13. The dispersive optical system of claim 1, wherein the layers of microprisms have an annular shape.

14. The dispersive optical system of claim 13, wherein the layers of microprisms comprise arrays of microprisms that are positioned concentrically around a central axis of the optical element.

15. An electricity generation system comprising the dispersive optical system of claim 1, and a photovoltaic cell positioned to receive the output of the dispersive optical system.

16. The electricity generation system of claim 15, wherein
the photovoltaic cell comprises a first region optimized for converting energy from a first wavelength band of light and a second region adjacent the first region optimized for converting energy from a second wavelength band of light, and
the photovoltaic cell is positioned such that the first region receives light from the dispersive optical system that predominately includes the first wavelength band, and the second region receives light from the dispersive optical system that predominately includes the second wavelength band.

17. The electricity generation system of claim 16, further comprising:
one or more corrective optical elements positioned between the dispersive optical system and the photovoltaic cell, the one or more corrective optical elements configured to collectively align the output from the dispersive optical system with the corresponding region of the photovoltaic cell.

18. A method of optical dispersion comprising:
focusing a light beam with an optical element;
refracting the light beam with a layer of high-dispersion microprisms; and
refracting the light beam with a layer of low-dispersion microprisms;
wherein the focusing and refracting steps optically concentrate and disperse the light beam into an output comprising a plurality of bands of light each having a different wavelength.

19. The method of claim 18, wherein one of the refracting steps comprises refracting the light beam with the one of the layers of microprisms formed directly on a rear surface of the optical element.

20. The method of claim 19, wherein the other one of the refracting steps comprises refracting the light beam with the other one of the layers of microprisms formed directly on a rear surface of the one of the layers of microprisms.

21. The method of claim 18, wherein the one of the refracting steps comprises refracting the light beam with an array of microprisms with each microprism extending linearly across the rear surface of the optical element.

22. The method of claim 18, wherein the focusing step and one of the refracting steps are performed by a single component that comprises the optical element integrally formed with and comprising the same material as one of the layers of microprisms.

23. The method of claim 18, further comprising the steps of directing the output onto a photovoltaic cell and generating electricity with the photovoltaic cell.

24. The method of claim 23, wherein
the photovoltaic cell comprises a first region optimized for converting energy from a first wavelength band of light and a second region adjacent the first region optimized for converting energy from a second wavelength band of light, and
the directing step comprises directing light that predominately includes the first wavelength band toward the first region and directing light that predominately includes to the second wavelength band toward the second region.

25. An energy generation system adapted to generate electricity from incident light, the system comprising:
at least one dispersive optical system configured to disperse an incident light beam into a plurality of different wavelength bands each directed to a target location, the optical system comprising:
an optical element configured to focus the light beam,
a layer of relatively higher-dispersion microprisms configured to at least disperse the light beam into the plurality of different wavelength bands, and
a layer of relatively lower-dispersion microprisms configured to at least direct the different wavelength bands to the target locations; and
at least one photovoltaic cell having a plurality of adjacent regions each optimized for converting energy from a different wavelength of light, the photovoltaic cell positioned relative to the target locations such that each region of the cell receives the band having the wavelength for which it is optimized.

26. The energy generation system of claim 25, comprising:
a plurality of said at least one photovoltaic cells arranged in a panel;
a plurality of said at least one dispersive systems, each configured to direct a corresponding light beam to an associated one of the photovoltaic cells; and
a frame disposed between the plurality of dispersive systems and the panel, the frame defining a plurality of cavities each corresponding to one of the dispersive systems and its associated photovoltaic cell.

27. The energy generation system of claim 25, further comprising a protective transparent layer disposed between a source of the incident light and the dispersive system.

28. The energy generation system of claim 25, wherein the relatively-higher dispersion microprisms are configured to cause deviation of the light beam from a desired propagation path and the relatively-lower dispersion microprisms are configured to cancel said deviation.
